(19) United States
(12) Patent Application Publication
(10) Pub. No.: US 2024/0290917 A1
(43) Pub. Date: Aug. 29, 2024

(54) LIGHT EMITTING DIODE AND LIGHT EMITTING PACKAGE INCLUDING THE SAME

(71) Applicant: SAMSUNG ELECTRONICS CO., LTD., Suwon-si (KR)

(72) Inventors: Hyongsik WON, Suwon-si (KR); Seongmin Kim, Suwon-si (KR); Jeongeun Yun, Suwon-si (KR); Jeongrok OH, Suwon-si (KR); Sungwoo Choi, Suwon-si (KR)

(73) Assignee: SAMSUNG ELECTRONICS CO., LTD., Suwon-si (KR)

(21) Appl. No.: 18/586,059

(22) Filed: Feb. 23, 2024

(30) Foreign Application Priority Data
Feb. 23, 2023 (KR) 10-2023-0024646

(51) Int. Cl. H01L 33/50; H01L 25/075; H01L 33/10; H01L 33/48

(52) U.S. Cl. CPC H01L 33/502; H01L 25/0753; H01L 33/10; H01L 33/486

(57) ABSTRACT

A light emitting diode is provided and includes a first light emitting chip configured to emit red light having a peak wavelength within a range of 580 nm to 700 nm, and a wavelength converter including an encapsulant and at least one phosphor that is inside the encapsulant. The at least one phosphor is configured to absorb a portion of the red light and emit first-type light having a peak wavelength that is greater than the peak wavelength of the red light.

### CROSS-REFERENCE TO RELATED APPLICATION

This application is based on and claims priority under 35 U.S.C. § 119 to Korean Patent Application No. 10-2023-0024646, filed on Feb. 23, 2023, in the Korean Intellectual Property Office, the disclosure of which is incorporated by reference herein in its entirety.

### BACKGROUND

### 1. Technical Field

Embodiments of the present disclosure relate to a light emitting diode and a light emitting package including the light emitting diode, and more particularly, to a light emitting diode having high energy efficiency and a light emitting package including the light emitting diode.

### 2. Description of Background Art

In general, illumination devices may include light emitting diodes (LED), and each of the LEDs may include at least one light emitting chip configured to emit light having a specific wavelength. For example, an illumination device including LEDs may include LED chips configured to emit light having various wavelengths, or may include an LED module in which at least one LED chip is combined with a wavelength conversion material such as a phosphor. Recently, life (or human)-friendly illumination is required when biological effects on humans and living organisms are considered in addition to general illumination functions.

### SUMMARY

Embodiments of the present disclosure provide a light emitting diode having high near-infrared emission efficiency and a light emitting package including the light emitting diode.

Embodiments of the present disclosure provide a light emitting diode configured to emit light having a wavelength at which bioenergy is activated, and a light emitting package including the light emitting diode.

According to embodiments of the present disclosure, a light emitting diode is provided and includes: a first light emitting chip configured to emit red light having a peak wavelength within a range of 580 nm to 700 nm; and a wavelength converter including an encapsulant and at least one phosphor that is inside the encapsulant, wherein the at least one phosphor is configured to absorb a portion of the red light and emit first-type light having a peak wavelength that is greater than the peak wavelength of the red light.

According to embodiments of the present disclosure, a light emitting package is provided and includes: a circuit board; and a plurality of light emitting diodes mounted on the circuit board, wherein the plurality of light emitting diodes includes a first light emitting diode. The first light emitting diode includes: a first light emitting chip configured to emit red light having a peak wavelength within a range of 580 nm to 700 nm; and a wavelength converter including an encapsulant and at least one phosphor that is inside the encapsulant, and wherein the at least one phosphor is configured to emit light in a near-infrared band by absorbing a portion of the red light.

According to embodiments of the present disclosure, a light emitting diode is provided and includes: a substrate; a first light emitting chip on the substrate and configured to emit red light having a peak wavelength within a range of 580 nm to 700 nm; a wavelength converter surrounding the first light emitting chip, the wavelength converter including an encapsulant and at least one phosphor that is inside the encapsulant; and a reflective layer including a cavity accommodating the wavelength converter, wherein the at least one phosphor is configured to emit first-type light in a near-infrared band by absorbing a portion of the red light.

Embodiments of the present disclosure are not limited thereto, and those skilled in the art will apparently understand other aspects of the present disclosure through the following description and the accompanying drawings.

### BRIEF DESCRIPTION OF DRAWINGS

Embodiments will be more clearly understood from the following detailed description taken in conjunction with the accompanying drawings in which:

FIG. 1 is a schematic cross-sectional view illustrating a light emitting diode according to an embodiment;

FIG. 2 is a schematic cross-sectional view illustrating a light emitting diode according to an embodiment;

FIG. 3 shows a spectrum of light emitted by a light emitting diode according to an embodiment;

FIG. 4 shows a spectrum of light emitted by a light emitting diode according to an embodiment;

FIG. 5 is a graph illustrating an adenosine triphosphate (ATP) action spectrum according to an embodiment;

FIG. 6 is a graph illustrating the ATP action spectrum together with a spectrum of light emitted by a light emitting diode according to an embodiment;

FIG. 7 is a schematic cross-sectional view illustrating a light emitting diode according to an embodiment;

FIG. 8 is a schematic cross-sectional view illustrating a light emitting diode according to an embodiment;

FIG. 9 is a schematic perspective view illustrating a light emitting package according to an embodiment;

FIG. 10 is a schematic cross-sectional view taken along line I-I′ across the light emitting package shown in FIG. 9;

FIG. 11 is a schematic perspective view illustrating an illumination device including a light emitting diode according to an embodiment;

FIG. 12 is a schematic perspective view illustrating an illumination device including a light emitting diode according to an embodiment; and

FIG. 13 is a schematic perspective view illustrating an illumination device including a light emitting diode according to an embodiment.

### DETAILED DESCRIPTION

Embodiments of the present disclosure may have various modifications and forms, and specific example embodiments are described with reference to the accompanying drawings. However, embodiments of the present disclosure are not limited to the specific example embodiments.

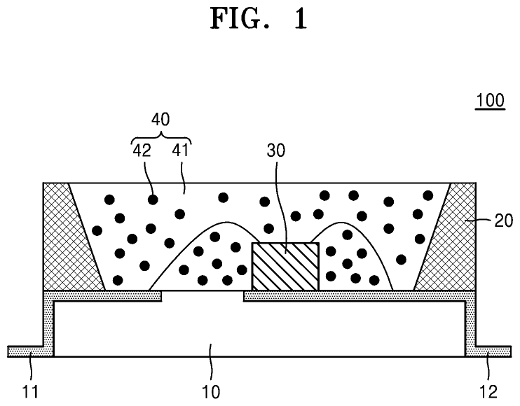

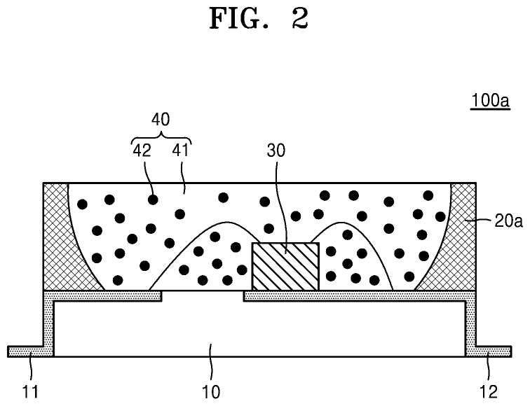

FIG. 1 is a schematic cross-sectional view illustrating a light emitting diode 100 according to an embodiment. FIG. 2 is a schematic cross-sectional view illustrating a light emitting diode 100a according to an embodiment.

Referring to FIGS. 1 and 2, the light emitting diode 100 (or the light emitting diode 100a) may include a substrate 10, a reflective layer 20 (or a reflective layer 20a), a first light emitting chip 30, and a wavelength converter 40. In some embodiments, the light emitting diode 100 (or the light emitting diode 100a) may include a pair of lead frames 11 and 12.

The substrate 10 may include an opaque resin or a resin having high reflectivity. For example, the substrate 10 may include a resin containing highly reflective powder (e.g., TiO₂ powder). In some embodiments, the substrate 10 may include a ceramic material that easily dissipates heat. In some embodiments, the substrate 10 may be a printed circuit board (PCB) that has a wiring pattern instead of the pair of lead frames 11 and 12.

In some embodiments, the pair of lead frames 11 and 12 may be disposed on the substrate 10. The pair of lead frames 11 and 12 may be electrically connected to the first light emitting chip 30. Although FIG. 1 illustrates that the pair of lead frames 11 and 12 is electrically connected to the first light emitting chip 30 by wire bonding, embodiments are not limited thereto.

The reflective layer 20 (or the reflective layer 20a) may reflect light emitted by the first light emitting chip 30 and the wavelength converter 40. In other words, the reflective layer 20 (or the reflective layer 20a) may reflect light emitted by the first light emitting chip 30 and the wavelength converter 40 toward an upper side of the wavelength converter 40. The reflective layer 20 (or the reflective layer 20a) may be disposed on the substrate 10 and the pair of lead frames 11 and 12 and may have a cavity accommodating the first light emitting chip 30 and the wavelength converter 40.

In some embodiments, as shown in FIG. 1, the cavity of the reflective layer 20 may be shaped such that the width of the cavity may decrease in a direction toward the substrate 10. In addition, as shown in FIG. 2, a cavity of the reflective layer 20a may have a cup shape. However, embodiments are not limited thereto, and the shape of the reflective layer 20 (or the reflective layer 20a) may be variously modified as long as light emitted by the first light emitting chip 30 and the wavelength converter 40 is reflected by the reflective layer 20 (or the reflective layer 20a) toward the upper side of the wavelength converter 40.

For example, the reflective layer 20 (or the reflective layer 20a) and the substrate 10 may include the same material (e.g., a resin containing highly reflective powder) and may be formed through the same process (e.g., injection molding). In some embodiments, the reflective layer 20 (or the reflective layer 20a) and the substrate 10 may be formed in one piece. In some embodiments, the reflective layer 20 (or the reflective layer 20a) may include a light-reflective material, for example, white powder such as SiO₂, TiO₂, or Al₂O₃ powder.

The first light emitting chip 30 may be configured to emit red light. For example, the first light emitting chip 30 may include a semiconductor layer of a first conductivity type and a semiconductor layer of a second conductivity type, and an active layer may be disposed between the semiconductor layer of the first conductivity type and the semiconductor layer of the second conductivity type. When a voltage difference is formed between the semiconductor layer of the first conductivity type and the semiconductor layer of the second conductivity type, light having a certain energy level may be emitted by recombination of holes and electrons in the active layer.

The active layer may have a multi-quantum well (MQW) structure in which quantum well layers and quantum barrier layers are alternately stacked. Each of the quantum well layers and the quantum barrier layers may have a thickness within a range of about 1 nm to about 50 nm. However, the active layer is not limited to having an MQW structure and may have a single quantum well structure.

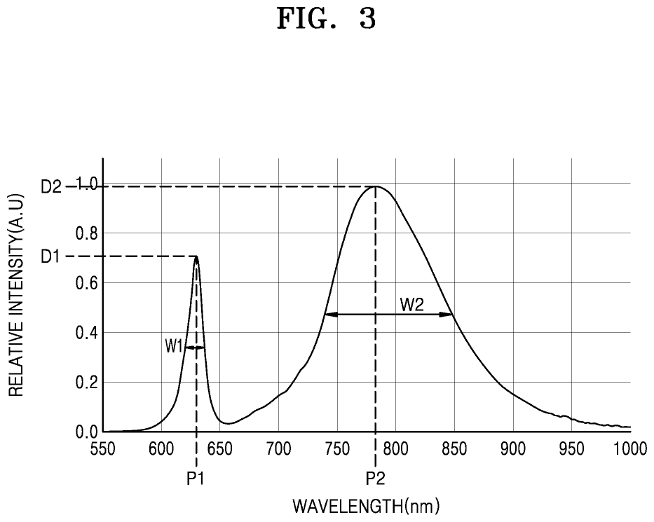

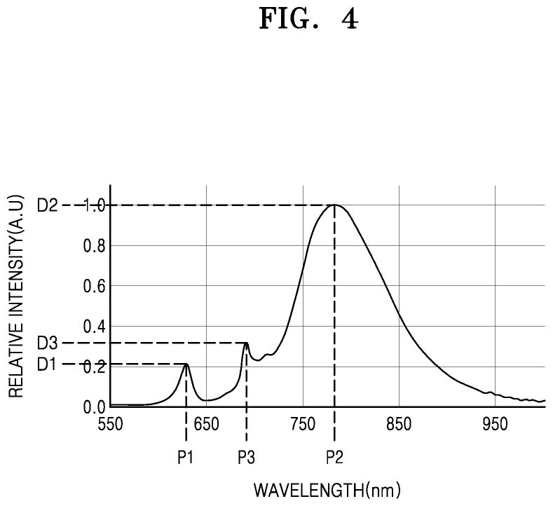

The first light emitting chip 30 may emit red light having a peak wavelength within a range of about 580 nm to about 700 nm. Spectra of red light emitted by the first light emitting chip 30 are described below with reference to FIGS. 3 and 4.

In some embodiments, the energy efficiency of the first light emitting chip 30 may be within a range of about 30% and about 95%. The energy efficiency of the first light emitting chip 30 refers to the ratio of the energy of red light emitted by the first light emitting chip 30 to energy input to the first light emitting chip 30. That is, the amount of energy output in the form of red light from the first light emitting chip 30 may be about 30% to about 95% of the amount of energy input to the first light emitting chip 30. For example, when 100 watts (W) is input to the first light emitting chip 30, the first light emitting chip 30 may emit red light at a power level of about 30 W to about 95 W.

The wavelength converter 40 may include an encapsulant 41 and at least one phosphor 42. The wavelength converter 40 may absorb some of red light emitted by the first light emitting chip 30 and may emit light having a peak wavelength that is different from a peak wavelength of the red light. For example, the phosphor 42 of the wavelength converter 40 may be excited by red light and emit first-type light having a peak wavelength that is greater than a peak wavelength of the red light.

The encapsulant 41 may surround the phosphor 42. In other words, the phosphor 42 may be provided inside the encapsulant 41. When the wavelength converter 40 includes a plurality of the phosphor 42, the plurality of the phosphor 42 may be dispersed inside the encapsulant 41.

In some embodiments, the encapsulant 41 may be a transparent resin. For example, the encapsulant 41 may include epoxy, silicone, modified silicone, a urethane resin, an oxetane resin, acrylic, polycarbonate, polyimide, or a combination thereof.

The phosphor 42 may emit light in a near-infrared band. A peak wavelength of light emitted by the phosphor 42 may be greater than a peak wavelength of red light. Spectra of light emitted by the phosphor 42 are described below with reference to FIGS. 3 and 4.

In some embodiments, the phosphor 42 may include one selected from the group consisting of Ca(Al_{12-x-y},Ga_{y})O₁₉:xCr³⁺ (0≤x≤1, 0≤y≤6), Lu₃Al₅O₁₂:Ce³⁺, Cr³⁺, La₃MgZrO₆:Cr³⁺, LiInS₁₂O₆:Cr³⁺, LiZnSnO:Cr³⁺, ScBO₃:Cr³⁺, and combinations thereof.

In some embodiments, first-type light emitted by the wavelength converter 40 may have a plurality of peak wavelengths. In other words, the first-type light may have a plurality of peak wavelengths that are greater than a peak wavelength of red light. In some embodiments, the first-type light may have at least one peak wavelength within a range of about 700 nm to about 1000 nm. For example, the first-type light may have a peak wavelength of 780 nm.

FIGS. 3 and 4 show spectra of light emitted by the light emitting diode 100 of the embodiment.

The spectra of light emitted by the light emitting diode 100 will now be described with reference to FIGS. 3 and 4 together with FIG. 1.

For example, FIG. 3 shows a spectrum of the light emitting diode 100 that is simulated by setting the peak wavelength of red light emitted by the first light emitting chip 30 to be 630 nm and the peak wavelength of the first-type light emitted by the plurality of the phosphor 42 to be 780 nm. FIG. 4 shows an actually measured spectrum of the light emitting diode 100.

The peak wavelength of red light emitted by the first light emitting chip 30 may be referred as a first wavelength P1, and the peak wavelength of the first-type light emitted by the wavelength converter 40 may be referred as a second wavelength P2. The second wavelength P2 may be greater than the first wavelength P1. For example, the second wavelength P2 may be in a near-infrared region that is greater than 700 nm, and the first wavelength P1 may be in a visible region that is less than 700 nm. For example, the first wavelength P1 may be within a range of about 580 nm to about 700 nm, and red light emitted by the first light emitting chip 30 may be orange-based or red-based light. The second wavelength P2 may be within a range of about 700 nm to about 1000 nm, and the first-type light emitted by the wavelength converter 40 may be near-infrared light.

In some embodiments, the luminous intensity at the first wavelength P1 of light emitted by the first light emitting chip 30 may be referred to as a first luminous intensity D1 and the luminous intensity at the second wavelength P2 of the first-type light emitted by the wavelength converter 40 may be referred to as a second luminous intensity D2. The second luminous intensity D2 may be greater than the first luminous intensity D1. The first luminous intensity D1 and the second luminous intensity D2 may vary depending on the degree to which the wavelength converter 40 absorbs red light emitted by the first light emitting chip 30. For example, as the wavelength converter 40 absorbs more red light emitted by the first light emitting chip 30, the first luminous intensity D1 may decrease and the second luminous intensity D2 may increase. For example, the first luminous intensity D1 may be less than 30% of the second luminous intensity D2.

In some embodiments, the first-type light emitted by the wavelength converter 40 may have a plurality of peak wavelengths. For example, the peak wavelengths of the first-type light may include a second wavelength P2 and a third wavelength P3 (refer to FIG. 4). The second wavelength P2 and the third wavelength P3 may be greater than the first wavelength P1. As shown in FIG. 4, the third wavelength P3 may be less than the second wavelength P2. In addition, when the first-type light has a third luminous intensity D3 at the third wavelength P3, the third luminous intensity D3 and the second luminous intensity D2 may be greater than the first luminous intensity D1. As shown in FIG. 4, the third luminous intensity D3 may be less than the second luminous intensity D2.

The first luminous intensity D1 and the second luminous intensity D2 may vary depending on the amount of the phosphor 42 included in the wavelength converter 40. In other words, the amount of light absorbed by the wavelength converter 40 may vary depending on the ratio of the mass of the phosphor 42 to the mass of the encapsulant 41 in the wavelength converter 40. For example, as the amount of the phosphor 42 increases, the wavelength converter 40 may absorb more light. In some embodiments, the weight of the phosphor 42 may be about 0.5 times to about 2 times the weight of the encapsulant 41.

Full width at half maximum, which is a term indicating the width of a function, may mean the difference between two values of an independent variable at which the function is equal to half of the maximum value of the function. Hereinafter, full width at half maximum refers to the difference between two wavelengths at which the luminous intensity is equal to half of the luminous intensity at a peak wavelength in a given light spectrum.

In some embodiments, the full width at half maximum of red light emitted by the first light emitting chip 30 may be referred to as a first width W1 (refer o FIG. 3) and the full width at half maximum of the first-type light emitted by the wavelength converter 40 may be referred to as a second width W2 (refer to FIG. 3). The second width W2 may be greater than the first width W1. For example, the first width W1 may be within a range of about 20 nm to about 50 nm. The second width W2 may be within a range of about 100 nm to about 300 nm. The first light emitting chip 30 emits red light through MQWs, and the wavelength converter 40 absorbs the red light emitted by the first light emitting chip 30 and emits the first-type light by converting the peak wavelength of the red light emitted by the first light emitting chip 30. That is, the first light emitting chip 30 and the wavelength converter 40 may emit light in different manners. Therefore, the first width W1 of red light emitted by the first light emitting chip 30 may be less than the second width W2 of the first-type light emitted by the wavelength converter 40.

In a light spectrum, the integral of luminous intensity with respect to wavelength (variable) may refer to the amount of light. The integral of the spectrum of light emitted by the light emitting diode 100 over all wavelengths may be the total amount of light. The integral of the spectrum of light emitted by the light emitting diode 100 over the wavelength of first-type light may be referred to as a first light amount. For example, when the peak wavelength of first-type light is 700 nm or more, the integral of the luminous intensity of light emitted by the light emitting diode 100 over the wavelength of 700 nm or more may be the first light amount. That is, the first light amount may refer to the integral of spectrum over a wavelength range corresponding to a near-infrared region.

The first light amount may be about 60% to about 100% of the total amount of light. That is, the amount of light obtained by integrating the luminous intensity over the wavelength of the first-type light may be about 60% to about 100% of the amount of light obtained by integrating the luminous intensity over all wavelengths of light emitted by the light emitting diode 100. For example, when the weight of the phosphor 42 is 0.5 times the weight of the encapsulant 41, the amount of light in the near-infrared band may be 65% of the total amount of light. When the weight of the phosphor 42 is twice the weight of the encapsulant 41, the amount of light in the near-infrared band may be 100% of the total amount of light.

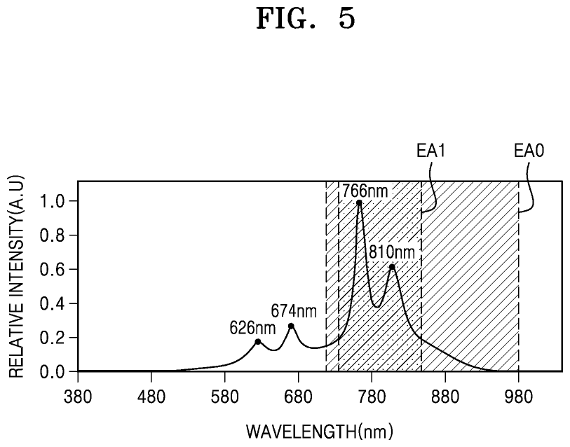

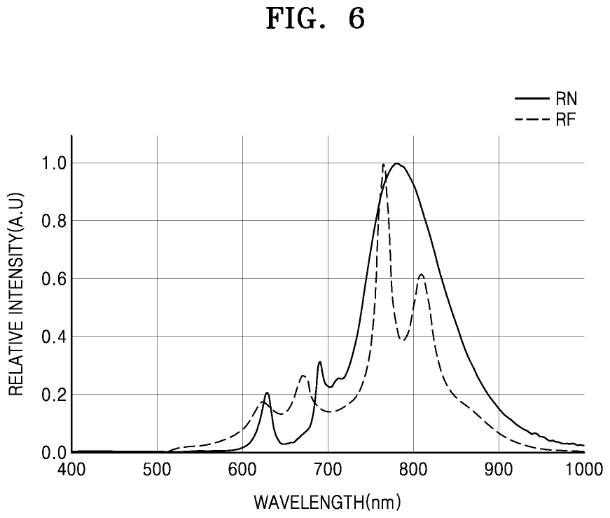

FIG. 5 is an adenosine triphosphate (ATP) action spectrum RF used in an embodiment. FIG. 6 is a graph illustrating the ATP action spectrum RF together with a spectrum RN of light emitted by the light emitting diode 100 of the embodiment.

The effects of light emitted by the light emitting diode 100 on the generation of ATP are now described with reference to FIGS. 5 and 6 together with FIG. 1.

In general, near-infrared light is absorbed by cytochrome c oxidase present in the inner membranes of mitochondria and thus promotes the production of ATP, which is an energy source of cells.

The ATP action spectrum RF has peak wavelengths similar to four absorption peak wavelengths (620 nm, 680 nm, 760 nm, and 820 nm) of the action spectrum of cytochrome c oxidase, but the four absorption peak wavelengths may be shifted to 626 nm, 674 nm, 766 nm, and 810 nm, respectively, depending on the transmittance of the skin.

In addition, the ATP action spectrum RF may be relatively low at 626 nm and 674 nm in a visible band and bands near the visible band and may be relatively high at 766 nm and 810 nm in a near-infrared band and bands near the near-infrared band.

Considering this practical action efficiency, a near-infrared band EA0 centered on a range of about 740 nm to about 900 nm in the ATP action spectrum shown in FIG. 5 may be defined as the “effective ATP action band.” In some embodiments, a band EA1 having peak wavelengths within a range of about 750 nm to about 850 nm may be set to be an effective ATP action band. The effective ATP action band (e.g., near-infrared band EA0 or band EA1) may be set by selecting a near-infrared band to minimize a visible band having low efficiency, and thus, the influence of basic illumination light (e.g., white light or color light) may be reduced by ATP generation promoting light according to an embodiment.

The spectrum RN of light emitted by the light emitting diode 100 may cover the vicinity of peak wavelengths of the ATP action spectrum RF. For example, the phosphor 42 of the wavelength converter 40 may be excited by red light and may emit first-type light covering the effective ATP action band. The first-type light may have a peak wavelength within a range of about 700 nm to about 1000 nm. In some embodiments, the first-type light generated through conversion in the phosphor 42 may have a peak wavelength within a range of about 750 nm to about 850 nm.

In addition, red light emitted by the first light emitting chip 30 may cover at least a portion of an absorption peak wavelength in the visible band. That is, the red light may have a peak wavelength within a range of about 580 nm to about 700 nm. In some embodiments, the red light may have a peak wavelength within a range of about 600 nm to about 650 nm.

The first-type light and the red light may pass through the skin of humans and may be absorbed by cytochrome c oxidase in cells, thereby substantially promoting the production of ATP, which is an energy source of cells.

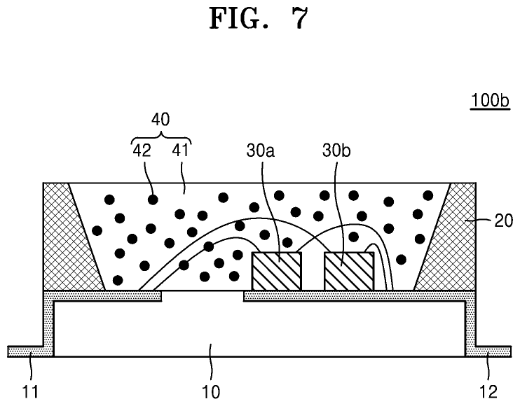

FIG. 7 is a schematic cross-sectional view illustrating a light emitting diode 100b according to an embodiment.

Referring to FIG. 7, the light emitting diode 100b may include a substrate 10, a reflective layer 20, a first light emitting chip 30a, a second light emitting chip 30b, and a wavelength converter 40. In some embodiments, the light emitting diode 100b may include a pair of lead frames 11 and 12.

Hereinafter, common structures between the light emitting diode 100b shown in FIG. 7 and the light emitting diode 100 shown in FIG. 1 may not be repeatedly described and differences therebetween are described. The substrate 10 and the reflective layer 20 shown in FIG. 7 may be substantially and respectively the same as the substrate 10 and the reflective layer 20 that are shown in FIG. 1.

The first light emitting chip 30a may be configured to emit red light. The first light emitting chip 30a may emit red light having a peak wavelength within a range of about 580 nm to about 700 nm. In some embodiments, the energy efficiency of the first light emitting chip 30a may be within a range of about 30% to about 95%.

In some embodiments, the second light emitting chip 30b may emit second-type light having a peak wavelength that is different from the peak wavelength of the first light emitting chip 30a. In some embodiments, the second light emitting chip 30b may be configured to emit blue light having a peak wavelength within a range of about 400 nm to about 465 nm.

In other embodiments, the second light emitting chip 30b may emit red light having a peak wavelength within a range of about 580 nm to about 700 nm. In some embodiments, the second light emitting chip 30b may have substantially the same peak wavelength as the peak wavelength of the first light emitting chip 30a.

Although FIG. 7 illustrates an embodiment in which the light emitting diode 100b includes two light emitting chips, embodiments are not limited thereto. In other embodiments, the light emitting diode 100b may include three or more light emitting chips. In this case, all of the light emitting chips may have the same peak wavelength or different peak wavelengths.

For example, the second light emitting chip 30b may include a semiconductor layer of a first conductivity type and a semiconductor layer of a second conductivity type, and an active layer may be disposed between the semiconductor layer of the first conductivity type and the semiconductor layer of the second conductivity type. When a voltage difference is formed between the semiconductor layer of the first conductivity type and the semiconductor layer of the second conductivity type, light having a certain energy level may be emitted by recombination of holes and electrons in the active layer.

The active layer may have an MQW structure in which quantum well layers and quantum barrier layers are alternately stacked. Each of the quantum well layers and the quantum barrier layers may have a thickness within a range of about 1 nm to about 50 nm. However, the active layer is not limited to an MQW structure and may have a single quantum well structure.

The light emitting diode 100b including a plurality of light emitting chips may emit relatively brighter light compared to another light emitting diode having the same area as the light emitting diode 100b. In addition, the light emitting diode 100b including a plurality of light emitting chips having different peak wavelengths may be configured such that the peak wavelengths may cover an ATP action spectrum.

The wavelength converter 40 may include an encapsulant 41 and at least one phosphor 42. The wavelength converter 40 may absorb a portion of light emitted by the first light emitting chip 30a and a portion of light emitted by the second light emitting chip 30b and may emit light having a peak wavelength that is different from the peak wavelengths of the absorbed light. For example, the phosphor 42 of the wavelength converter 40 may be excited by light emitted by the first light emitting chip 30a and the second light emitting chip 30b and may emit the first-type light having a peak wavelength greater than the peak wavelengths of the absorbed light.

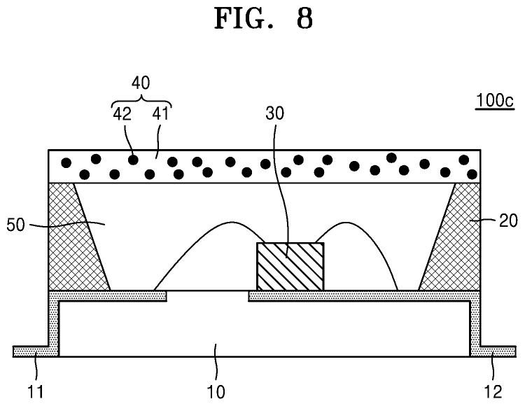

FIG. 8 is a schematic cross-sectional view illustrating a light emitting diode 100c according to an embodiment.

Referring to FIG. 8, the light emitting diode 100c may include a substrate 10, a reflective layer 20, a first light emitting chip 30, an encapsulant 50, and a wavelength converter 40. In some embodiments, the light emitting diode 100c may include a pair of lead frames 11 and 12.

Hereinafter, common structures between the light emitting diode 100c shown in FIG. 8 and the light emitting diode 100 shown in FIG. 1 may not be repeatedly described and differences therebetween are described.

The substrate 10 may be substantially the same as the substrate 10 shown in FIG. 1.

The reflective layer 20 may reflect light emitted by the first light emitting chip 30 and the wavelength converter 40. In other words, the reflective layer 20 may reflect light emitted by the first light emitting chip 30 and the wavelength converter 40 toward an upper side of the wavelength converter 40. The reflective layer 20 may be disposed on the substrate 10 and the pair of lead frames 11 and 12 and may have a cavity accommodating the first light emitting chip 30 and the encapsulant 50. The cavity may be shaped such that the width of the cavity may decrease in a direction toward the substrate 10.

The encapsulant 50 may fill the cavity of the reflective layer 20. The encapsulant 50 may surround the first light emitting chip 30. The encapsulant 50 may protect the first light emitting chip 30 from the outside. The encapsulant 50 may include a transparent resin. For example, the encapsulant 50 may include epoxy, silicone, modified silicone, a urethane resin, an oxetane resin, acrylic, polycarbonate, polyimide, or a combination thereof.

The first light emitting chip 30 may be configured to emit red light. The first light emitting chip 30 may emit red light having a peak wavelength within a range of about 580 nm to about 700 nm. In some embodiments, the energy efficiency of the first light emitting chip 30 may be within a range of about 30% to about 95%. The first light emitting chip 30 may be substantially the same as the first light emitting chip 30 shown in FIG. 1.

The wavelength converter 40 may be disposed on the encapsulant 50. In other words, the wavelength converter 40 may be disposed on an upper surface of the encapsulant 50. In some embodiments, the wavelength converter 40 may have a constant thickness. In some embodiments, the wavelength converter 40 may extend on the upper surface of the encapsulant 50 and the upper surface of the reflective layer 20. That is, the wavelength converter 40 may cover the upper surface of the encapsulant 50 and the upper surface of the reflective layer 20.

The wavelength converter 40 may include an encapsulant 41 and at least one phosphor 42. The wavelength converter 40 may absorb a portion of red light emitted by the first light emitting chip 30 and may emit light having a peak wavelength that is different from the peak wavelength of the red light. For example, the phosphor 42 of the wavelength converter 40 may be excited by red light and may emit the first-type light having a peak wavelength that is greater than the peak wavelength of the red light.

Light emitted by the first light emitting chip 30 may pass through the wavelength converter 40 toward the outside of the light emitting diode 100c. In this case, at least a portion of light emitted by the first light emitting chip 30 may be absorbed in the phosphor 42 while the light passes through the wavelength converter 40. The phosphor 42 absorbing at least a portion of light emitted by the first light emitting chip 30 may emit the first-type light having a peak wavelength that is different from the peak wavelength of the portion of the light emitted by the first light emitting chip 30.

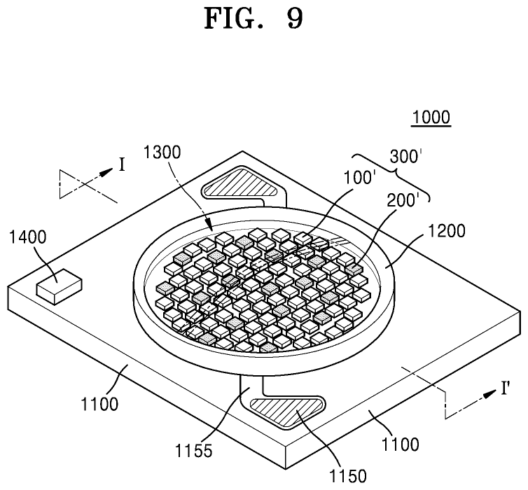

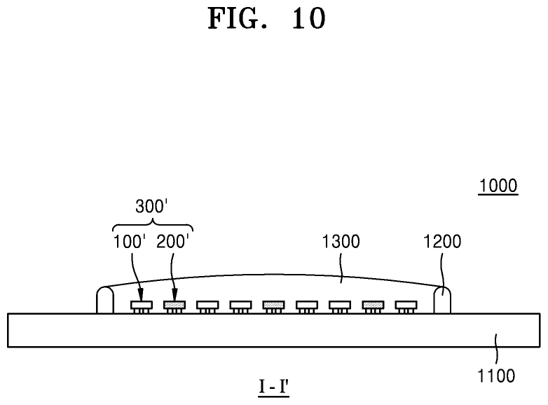

FIG. 9 is a schematic perspective view illustrating a light emitting package 1000 according to an embodiment. FIG. 10 is a schematic cross-sectional view taken along line I-I′ across the light emitting package 1000 shown in FIG. 9.

Referring to FIG. 9 and FIG. 10 together with FIG. 1, the light emitting package 1000 of the embodiment may include a circuit board 1100, a plurality of light emitting diodes 300′, a dam 1200, a sealing material 1300, and a driving control chip 1400.

The circuit board 1100 may include a conductive material and an insulating material. A metal pattern 1155 connected to the light emitting diodes 300′ and a terminal 1150 connected to the metal pattern 1155 may be provided on an upper surface of the circuit board 1100.

The circuit board 1100 may be, for example, an FR4 PCB and may include: an organic resin containing epoxy, a triazine, silicone, polyimide, or the like; a ceramic such as SiN, AlN, or Al₂O₃; or a metal and a metal compound. In some embodiments, the circuit board 1100 may include a PCB, a metal core PCB (MCPCB), a metal-based PCB (MPCB), a flexible PCB (FPCB), a copper clad laminate (CCL), a metal-based CCL (MCCL), or the like.

The metal pattern 1155 may be electrically connected to the light emitting diodes 300′ and may be electrically connected to an external power source through the terminal 1150, and thus, an electrical signal may be applied to the light emitting diodes 300′ through the metal pattern 155. The metal pattern 1155 and the terminal 1150 may be of a conductive thin film type. For example, the metal pattern 1155 and the terminal 1150 may include copper foil.

The dam 1200 may be disposed on the circuit board 1100 to surround the light emitting diodes 300′ and define an internal light emitting region. The dam 1200 may protrude from the upper surface of the circuit board 1100 and may have a ring shape. In the current embodiment, however, the circuit board 1100 and the dam 1200 are not respectively limited to a rectangular shape and a circular shape, and thus, the arrangement of the light emitting diodes 300′ may be variously changed. Furthermore, in some embodiments, the dam 1200 may be omitted.

The sealing material 1300 may fill a space defined by the dam 1200 and cover the light emitting diodes 300′. The sealing material 1300 may be formed in an upwardly convex dome shape to adjust the beam angle of light that is emitted outward. However, the sealing material 1300 is not limited thereto.

The sealing material 1300 may include a light-transmitting material such that light generated by the light emitting diodes 300′ may be output through the sealing material 1300. As the light-transmitting material, for example, a resin such as silicone or epoxy may be used. The sealing material 1300 may be formed by injecting a resin onto the circuit board 1100 and curing the resin by heating, light irradiation, or elapse of time. In some embodiments, the sealing material 1300 may include a light-reflecting material to diffuse light that is output to the outside. As the light-reflecting material, for example, white powder such as SiO₂, TiO₂, or Al₂O₃ powder may be used. In some embodiments, however, the sealing material 1300 may be omitted, and each of the light emitting diodes 300′ may include a lens.

The light emitting diodes 300′ may be disposed on the circuit board 1100. Electrodes and bumps may be attached to lower portions of the light emitting diodes 300′. The electrodes may include a conductive material and may be electrically connected to an electrode pattern of the circuit board 1100 through bumps. That is, each of the light emitting diodes 300′ may be electrically connected to the electrode pattern of the circuit board 1100 through the electrodes and the bumps.

The light emitting diodes 300′ may be arranged apart from each other on the circuit board 1100. The light emitting diodes 300′ may be dispersed inside the dam 1200. That is, the shape in which the light emitting diodes 300′ are arranged may vary depending on the shape of the dam 1200.

The light emitting diodes 300′ may include first light emitting diodes 100′ and second light emitting diodes 200′. At least some of the light emitting diodes 300′ may be the first light emitting diodes 100′. In some embodiments, all of the light emitting diodes 300′ may be the first light emitting diodes 100′. In addition, when some of the light emitting diodes 300′ are the first light emitting diodes 100′, the others may be the second light emitting diodes 200′.

Although FIG. 9 illustrates an embodiment in which the light emitting diodes 300′ include two types of light emitting diodes, embodiments are not limited thereto. In some embodiments, the light emitting diodes 300′ may all be of one type or may include three or more types of light emitting diodes.

The first light emitting diodes 100′ may each include a first light emitting chip and a first wavelength converter. The first light emitting chip may be configured to emit red light having a peak wavelength within a range of about 580 nm to about 700 nm. The first wavelength converter may absorb red light emitted by the first light emitting chip 30 and may emit light in a near-infrared band. For example, a phosphor of the first wavelength converter may absorb red light and emit light having a peak wavelength that is greater than the peak wavelength of the red light. Each of the first light emitting diodes 100′ may finally emit red light by combining light emitted by the first light emitting chip with light emitted by the first wavelength converter. The first light emitting diodes 100′ may be the same as the light emitting diode 100 described with reference to FIG. 1, the light emitting diode 100a described with reference to FIG. 2, the light emitting diode 100b described with reference to FIG. 7, or the light emitting diode 100c described with reference to FIG. 8.

The second light emitting diodes 200′ may each include a second light emitting chip and a second wavelength converter. The second light emitting chip may be configured to emit second-type light having a peak wavelength that is different from the peak wavelength of the first light emitting chip. The second wavelength converter may include an encapsulant and a phosphor provided inside the encapsulant. The second wavelength converter may absorb the second-type light and emit light in a near-infrared band. Each of the second light emitting diodes 200′ may finally emit white light by combining light emitted by the second light emitting chip with light emitted by the second wavelength converter.

In some embodiments, the second light emitting chip may emit blue light having a peak wavelength within a range of about 400 nm to about 465 nm, and the second wavelength converter may absorb a portion of the blue light and emit light in a near-infrared band. For example, the phosphor of the second wavelength converter may absorb blue light and emit light having a peak wavelength within a range of about 700 nm to about 1000 nm.

The driving control chip 1400 may include a light emitting diode driving unit and a signal control unit configured to provide a driving signal for controlling the light emitting diode driving unit. The light emitting diode driving unit may be connected to a power supply unit to receive power and may supply current controlled by a driving signal of the signal control unit to the light emitting diodes 300′. In the current embodiment, the light emitting diode driving unit may be controlled to provide different currents independently to the light emitting diodes 300′. In some embodiments, the driving control chip 1400 may supply current only to the first light emitting diodes 100′ or the second light emitting diodes 200′ among the light emitting diodes 300′. Therefore, according to user's control, the light emitting package 1000 may adjust the type of light emitting diodes that emit light.

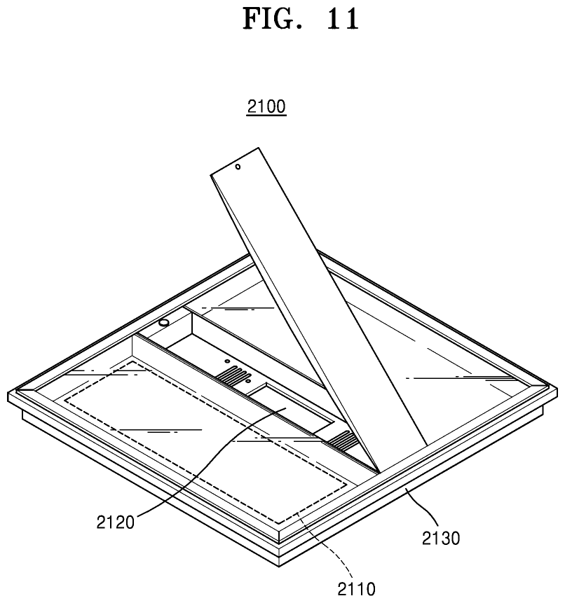

FIG. 11 is a perspective view schematically illustrating a flat panel illumination device 2100 including light emitting diodes according to embodiments.

Referring to FIG. 11, the flat panel illumination device 2100 may include a light source module 2110, a power supply device 2120, and a housing 2130. According to an embodiment, the light source module 2110 may include light emitting diodes and the power supply device 2120 may include a power supply unit configured to supply power to the light source module 2110.

The power supply device 2120 may be configured to supply power to the light source module 2110. The housing 2130 may have an accommodation space to accommodate the light source module 2110 and the power supply device 2120 therein, and may be formed in a hexahedral shape having an open side. However, the housing 2130 is not limited thereto. The light source module 2110 may be positioned to emit light toward the open side of the housing 2130.

The light source module 2240 may include the light emitting package 1000 shown in FIG. 9. The light source module 2110 may include, as a light source, at least one selected from the group consisting of the light emitting diode 100 described with reference to FIG. 1, the light emitting diode 100a described with reference to FIG. 2, the light emitting diode 100b described with reference to FIG. 7, and the light emitting diode 100c described with reference to FIG. 8. The light source module 2110 may have a flat shape as a whole.

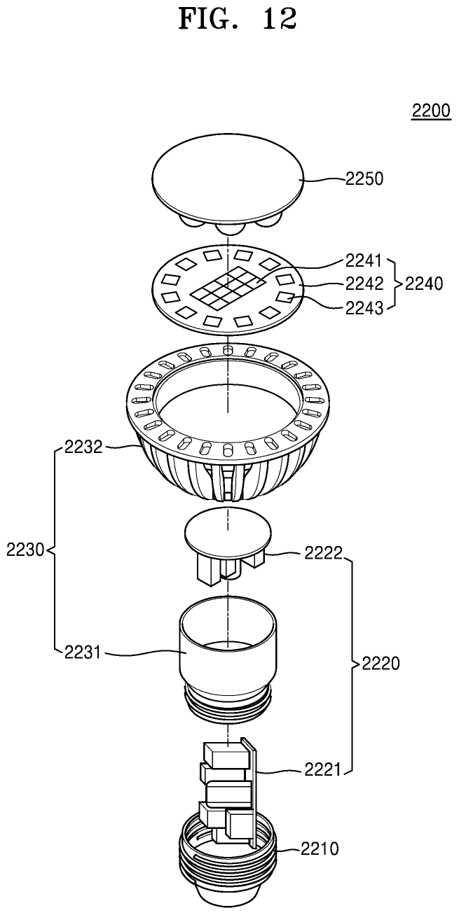

FIG. 12 is an exploded perspective view schematically illustrating an illumination device 2200 including light emitting diodes according to embodiments.

Referring to FIG. 12, the illumination device 2200 may include a socket 2210, a power unit 2220, a heat dissipation unit 2230, a light source module 2240, and an optical unit 2250. According to an embodiment, the light source module 2240 may include light emitting diodes, and the power unit 2220 may include a power supply unit configured to supply power to the light source module 2240.

The socket 2210 may replace a socket of an existing illumination device. Power may be supplied to the illumination device 2200 through the socket 2210. As illustrated in FIG. 12, the power unit 2220 may be assembled in a state in which a first power unit 2221 and a second power unit 2222 are separate from each other. The heat dissipation unit 2230 may include an internal dissipation unit 2231 and an external dissipation unit 2232, and the internal dissipation unit 2231 may be directly connected to the light source module 2240 and/or the power unit 2220 to transfer heat to the external dissipation unit 2232. The optical unit 2250 may include an internal optical unit and an external optical unit, and may evenly scatter light emitted by the light source module 2240.

The light source module 2240 may receive power from the power unit 2220 and emit light toward the optical unit 2250. The light source module 2240 may include at least one emitting package 2241, a board 2242, and a controller 2243, and the controller 2243 may store information on the driving of the at least one light emitting package 2241.

The at least one light emitting package 2241 of the light source module 2240 may include the light emitting package 1000 described with reference to FIG. 9. The at least one light emitting package 2241 may include at least one selected from the group consisting of the light emitting diode 100 described with reference to FIG. 1, the light emitting diode 100a described with reference to FIG. 2, the light emitting diode 100b described with reference to FIG. 7, and the light emitting diode 100c described with reference to FIG. 8.

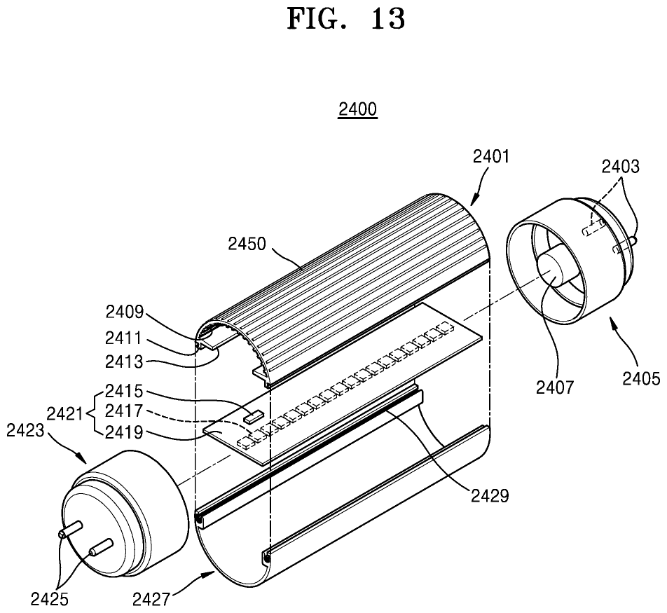

FIG. 13 is an exploded perspective view schematically illustrating a bar-type illumination device 2400 including light emitting diodes according to embodiments.

Referring to FIG. 13, the bar-type illumination device 2400 includes a heat dissipation member 2401, a cover 2427, a light source module 2421, a first socket 2405, and a second socket 2423.

A plurality of heat dissipation fins 2450 and 2409 may be formed in a concavo-convex shape on an inner and/or an outer surface of the heat dissipation member 2401, and the heat dissipation fins 2450 and 2409 may be designed to have various shapes and intervals. Supports 2413 having a protruding shape are formed inside the heat dissipation member 2401. The light source module 2421 may be fixed to the supports 2413. Locking protrusions 2411 may be formed at both ends of the heat dissipation member 2401.

Locking grooves 2429 may be formed in the cover 2427, and the locking protrusions 2411 of the heat dissipation member 2401 may be coupled to the locking grooves 2429 in a hook coupling manner. The positions of the locking grooves 2429 are interchangeable with the positions of the locking protrusions 2411. For example, the cover 2427 may include the locking protrusions 2411, and the heat dissipation member 2401 may include the locking grooves 2429.

The light source module 2421 may include a PCB 2419, a light source 2417, and a controller 2415. The controller 2415 may store information on the driving of the light source 2417. Circuit wires for operating the light source 2417 may be formed on the PCB 2419. In addition, components for operating the light source 2417 may be included in the light source module 2421. The light source 2417 may include the light emitting package 1000 described with reference to FIG. 9. The light source 2417 may include at least one selected from the group consisting of the light emitting diode 100 described with reference to FIG. 1, the light emitting diode 100a described with reference to FIG. 2, the light emitting diode 100b described with reference to FIG. 7, and the light emitting diode 100c described with reference to FIG. 8.

The first socket 2405 and the second socket 2423 are a pair of sockets configured to be coupled to both ends of a cylindrical cover unit formed by the heat dissipation member 2401 and the cover 2427. For example, the first socket 2405 may include electrode terminals 2403 and a power device 2407, and dummy terminals 2425 may be disposed on the second socket 2423. In addition, an optical sensor and/or a communication module may be embedded in any one of the first socket 2405 and the second socket 2423. For example, the optical sensor and/or the communication module may be embedded in the second socket 2423 on which the dummy terminals 2425 are disposed. In another example, the optical sensor and/or the communication module may be embedded in the first socket 2405 on which the electrode terminals 2403 are disposed.

While example embodiments of the present disclosure have been particularly shown and described in the present disclosure, it will be understood that various changes in form and details may be made therein without departing from the spirit and scope of the present disclosure.

What is claimed is:

1. A light emitting diode comprising:
a first light emitting chip configured to emit red light having a peak wavelength within a range of 580 nm to 700 nm; and
a wavelength converter comprising an encapsulant and at least one phosphor that is inside the encapsulant,
wherein the at least one phosphor is configured to absorb a portion of the red light and emit first-type light having a peak wavelength that is greater than the peak wavelength of the red light.

2. The light emitting diode of claim 1, wherein the first-type light comprises near-infrared light having a peak wavelength within a range of 700 nm to 1000 nm.

3. The light emitting diode of claim 1, wherein a full width at half maximum of the first-type light is greater than a full width at half maximum of the red light.

4. The light emitting diode of claim 3, wherein the full width at half maximum of the first-type light is within a range of 100 nm to 300 nm.

5. The light emitting diode of claim 1, wherein a luminous intensity at the peak wavelength of the first-type light is greater than a luminous intensity at the peak wavelength of the red light.

6. The light emitting diode of claim 1, wherein a luminous intensity at the peak wavelength of the red light is 30% or less of a luminous intensity at the peak wavelength of the first-type light.

7. The light emitting diode of claim 1, wherein an amount of the first-type light is 60% to 100% of a total amount of light that the light emitting diode is configured to emit.

8. The light emitting diode of claim 1, wherein a weight of the at least one phosphor is 0.5 times to 2 times a weight of the encapsulant.

9. The light emitting diode of claim 1, wherein an energy efficiency of the first light emitting chip is within a range of 30% to 95%.

10. The light emitting diode of claim 1, wherein the first-type light has a plurality of peak wavelengths.

11. The light emitting diode of claim 1, wherein the at least one phosphor comprises at least one from among Ca(Al_{12-x-y},Ga_{y})O₁₉:xCr³⁺ (0≤x≤1, 0≤y≤6), Lu₃Al₅O₁₂:Ce³⁺, Cr³⁺, La₃MgZrO₆:Cr³⁺, LiInS₁₂O₆:Cr³⁺, LiZnSnO:Cr³⁺, and ScBO₃:Cr³⁺.

12. The light emitting diode of claim 1, further comprising a reflective layer surrounding a lateral surface of the wavelength converter.

13. The light emitting diode of claim 1, further comprising a second light emitting chip configured to emit second-type light having a peak wavelength that is different from the peak wavelength of the red light.

14. The light emitting diode of claim 1, further comprising a second light emitting chip configured to emit red light having a peak wavelength within a range of 580 nm to 700 nm.

15. The light emitting diode of claim 14, wherein the peak wavelength of the red light that the second light emitting chip is configured to emit is equal to the peak wavelength of the red light that the first light emitting chip is configured to emit.

16. A light emitting package comprising:
a circuit board; and
a plurality of light emitting diodes mounted on the circuit board,
wherein the plurality of light emitting diodes comprises a first light emitting diode,
wherein the first light emitting diode comprises:
a first light emitting chip configured to emit red light having a peak wavelength within a range of 580 nm to 700 nm; and
a wavelength converter comprising an encapsulant and at least one phosphor that is inside the encapsulant, and
wherein the at least one phosphor is configured to emit light in a near-infrared band by absorbing a portion of the red light.

17. The light emitting package of claim 16, wherein the plurality of light emitting diodes further comprises a second light emitting diode,
wherein the second light emitting diode comprises:
a second light emitting chip configured to emit second-type light having a peak wavelength that is different from the peak wavelength of the red light that the first light emitting chip is configured to emit; and
a wavelength converter comprising an encapsulant and at least one phosphor that is inside the encapsulant, and
wherein the at least one phosphor of the second light emitting diode is configured to absorb a portion of the second-type light and convert the portion of the second-type light into near-infrared light.

18. The light emitting package of claim 17, wherein the second light emitting diode is configured to emit white light, and
the first light emitting diode is configured to emit red light.

19. A light emitting diode comprising:
a substrate;
a first light emitting chip on the substrate and configured to emit red light having a peak wavelength within a range of 580 nm to 700 nm;
a wavelength converter surrounding the first light emitting chip, the wavelength converter comprising an encapsulant and at least one phosphor that is inside the encapsulant; and
a reflective layer comprising a cavity accommodating the wavelength converter,
wherein the at least one phosphor is configured to emit first-type light in a near-infrared band by absorbing a portion of the red light.

20. The light emitting diode of claim 19, wherein the first-type light has a peak wavelength within a range of 700 nm to 1000 nm,
a luminous intensity at the peak wavelength of the first-type light is greater than a luminous intensity at the peak wavelength of the red light, and
an amount of the first-type light is 60% to 100% of a total amount of light that the light emitting diode is configured to emit.
